(19) United States
(12) Patent Application Publication
(10) Pub. No.: US 2026/0213039 A1
(43) Pub. Date: Jul. 23, 2026

(54) WIRE HARNESS

(71) Applicant: Yazaki Corporation, Tokyo (JP)

(72) Inventors: Katsunori SATO, Shizuoka (JP); Tatsuya Oga, Shizuoka (JP)

(73) Assignee: Yazaki Corporation, Tokyo (JP)

(21) Appl. No.: 19/578,017

(22) Filed: Mar. 25, 2026

Related U.S. Application Data
(63) Continuation of application No. PCT/JP2025/004309, filed on Feb. 10, 2025.

(30) Foreign Application Priority Data
Mar. 14, 2024 (JP) 2024-039893

(51) Int. Cl. H01B 7/00; H01M 50/298; H01M 50/503

(52) U.S. Cl. CPC H01B 7/0045; H01M 50/298; H01M 50/503

(57) ABSTRACT

A wire harness includes a flat wiring member formed in a U shape, a first case that holds a first portion, a second case that holds a second portion, and a rotating structure. The flat wiring member having a straight line shape includes a first folded portion and a second folded portion. The first folded portion has a configuration in which an intermediate portion is folded back along a folding line in an extending direction of the first portion. The second folded portion has a configuration in which the second portion is folded back along a folding line orthogonal to the extending direction. The rotating structure is configured to form the second folded portion in the second portion by rotating the first case and the second case relative to each other.

### CROSS-REFERENCE TO RELATED APPLICATION

This application is a continuation application of International Application No. PCT/JP2025/004309 filed on Feb. 10, 2025 which claims the benefit of priority from Japanese Patent Application No. 2024-039893 filed on Mar. 14, 2024 and designating the U.S., the entire contents of which are incorporated herein by reference.

### BACKGROUND OF THE INVENTION

### 1. Field of the Invention

The present invention relates to a wire harness.

### 2. Description of the Related Art

There are conventionally known flat wiring members such as a flexible printed circuit board. JP 2015-170699 A discloses a flexible printed circuit board capable of easily implementing elongated wire arrangement. The flexible printed circuit board of JP 2015-170699 A includes: a first band-shaped member and a second band-shaped member each having a conductive portion and an insulating portion covering the conductive portion; and a first coupling member that couples a first end of the first band-shaped member and a first end of the second band-shaped member to each other.

The flat wiring member formed in a U shape is desired to be elongated into a straight line shape. When the flat wiring member formed in the U shape is used, the manufacturing cost and the mounting cost of the flat wiring member can be reduced.

### SUMMARY OF THE INVENTION

An object of the present invention is to provide a wire harness capable of elongating a flat wiring member formed in a U shape into a straight line shape.

In order to achieve the above mentioned object, a wire harness according to one aspect of the present invention includes: a flat wiring member formed in a U shape, the flat wiring member including a first portion having a straight line shape, a second portion having a straight line shape, and an intermediate portion connecting an end of the first portion and an end of the second portion to each other; a first case that holds the first portion; a second case that holds the second portion; and a rotating structure that rotates the first case and the second case relative to each other, wherein the first case and the second case can be engaged with each other in a state where the flat wiring member has a straight line shape, the flat wiring member having a straight line shape has a configuration in which the second portion extends on an extension line of the first portion in plan view, the flat wiring member having a straight line shape includes a first folded portion and a second folded portion, the intermediate portion is folded along a folding line in the first folded portion, the folding line extending in an extending direction in which the first portion extends, the second portion is folded, in the second folded portion, along a folding line orthogonal to the extending direction so as to allow a part of the second portion to overlap with the intermediate portion, and the rotating structure is configured to form the second folded portion in the second portion by rotating the first case and the second case relative to each other.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view of a wire harness according to an embodiment;

FIG. 2 is a perspective view of a flat wiring member according to the embodiment;

FIG. 3 is a plan view of the flat wiring member according to the embodiment;

FIG. 4 is a plan view of a case according to the embodiment;

FIG. 5 is a perspective view of the case according to the embodiment;

FIG. 6 is a plan view of the wire harness according to the embodiment;

FIG. 7 is a plan view of the wire harness according to the embodiment;

FIG. 8 is a plan view of the wire harness according to the embodiment;

FIG. 9 is a cross-sectional view of the wire harness according to the embodiment;

FIG. 10 is a perspective view of the flat wiring member according to the embodiment;

FIG. 11 is a cross-sectional view of the wire harness according to the embodiment;

FIG. 12 is a perspective view of the wire harness according to the embodiment;

FIG. 13 is a cross-sectional view of the wire harness according to the embodiment;

FIG. 14 is a diagram illustrating an example of a rotating structure according to the embodiment;

FIG. 15 is a diagram illustrating an example of the rotating structure according to the embodiment;

FIG. 16 is a diagram illustrating an example of the rotating structure according to the embodiment;

FIG. 17 is a diagram illustrating an example of the rotating structure according to the embodiment;

FIG. 18 is a diagram illustrating an example of the rotating structure according to the embodiment;

FIG. 19 is a perspective view of a first case and a second case according to a modification of the embodiment;

FIG. 20 is a perspective view of a wire harness according to a modification of the embodiment;

FIG. 21 is a perspective view of the wire harness according to the modification of the embodiment; and

FIG. 22 is a perspective view of the wire harness according to the modification of the embodiment.

### DETAILED DESCRIPTION OF THE PREFERRED EMBODIMENTS

Hereinafter, a wire harness according to an embodiment of the present invention will be described in detail with reference to the drawings. Note that the present invention is not limited by the embodiment. Moreover, components in the following embodiment include those that are easily conceivable for those skilled in the art or substantially identical.

### Embodiment

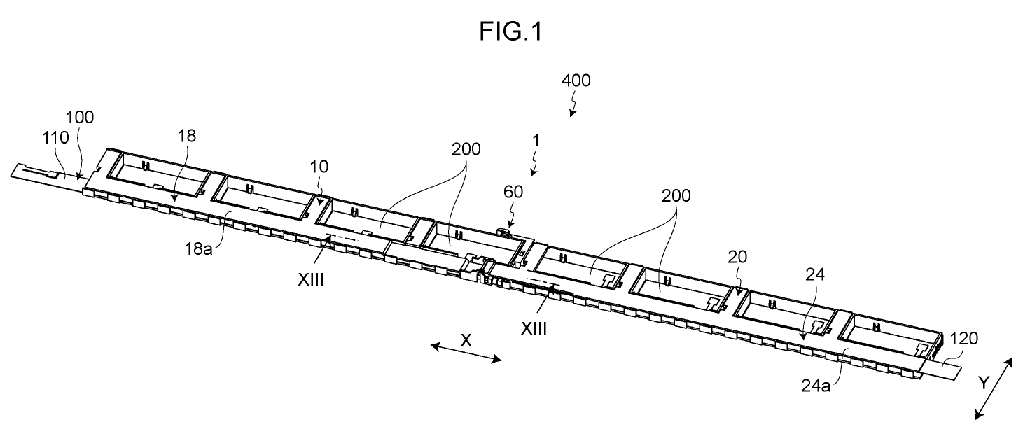

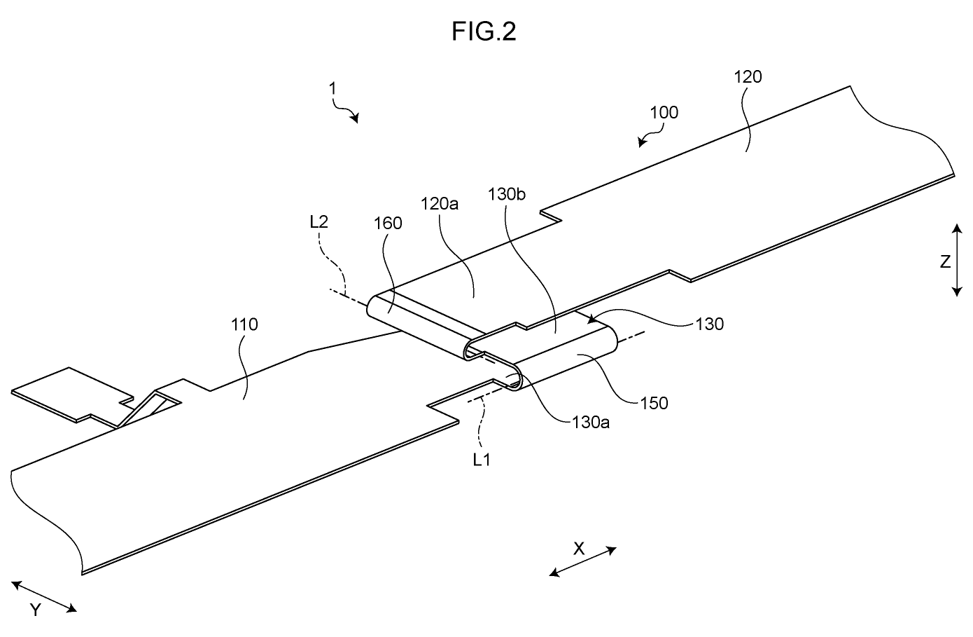

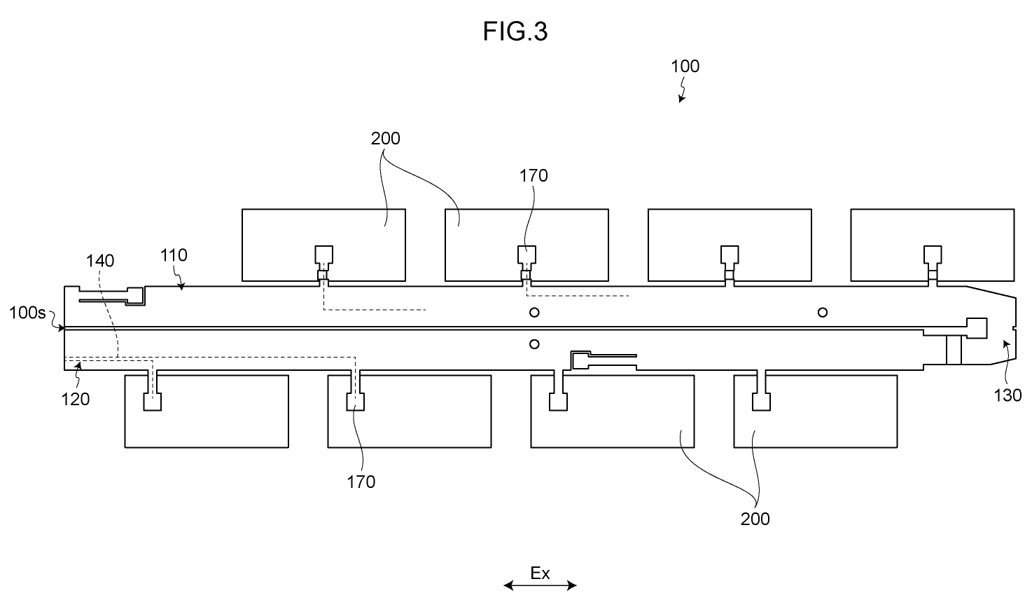

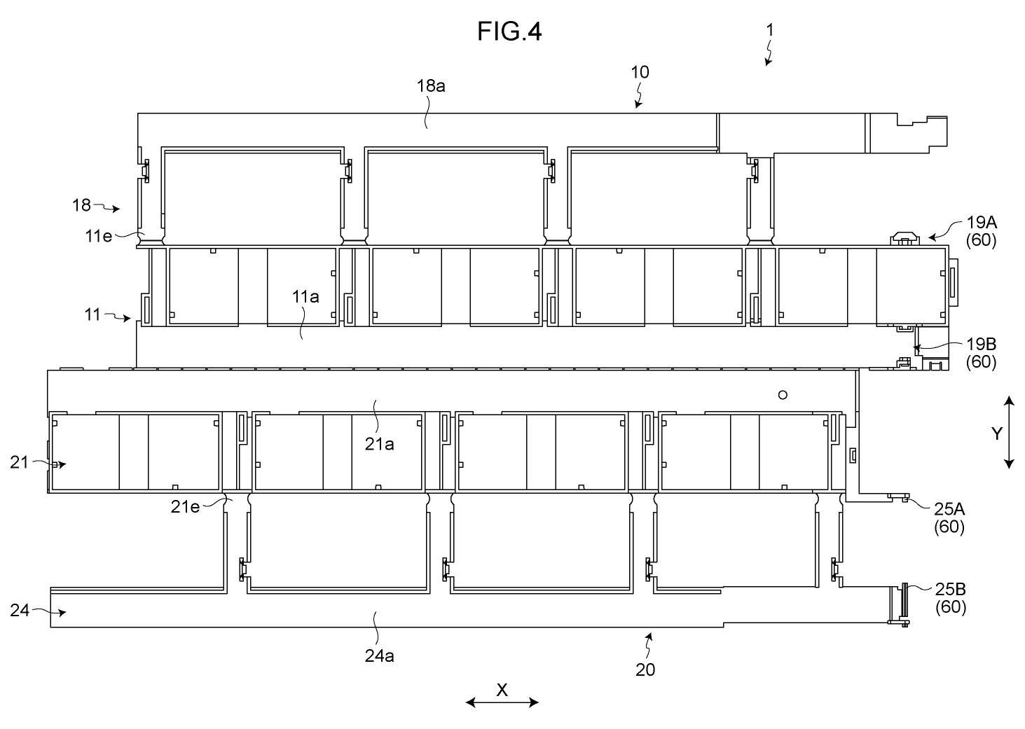

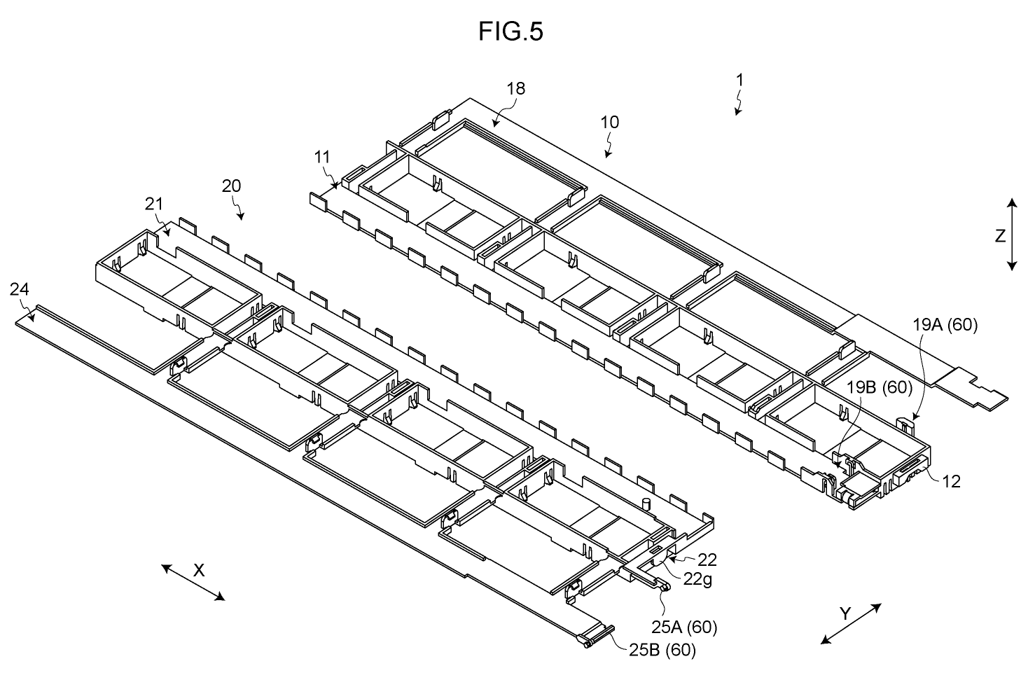

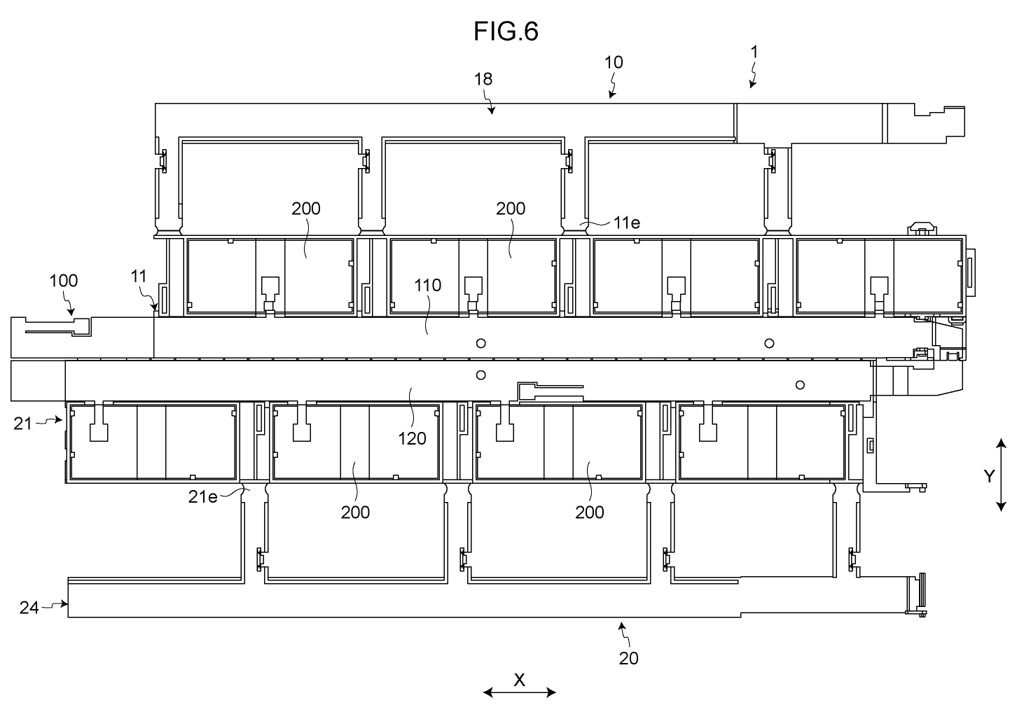

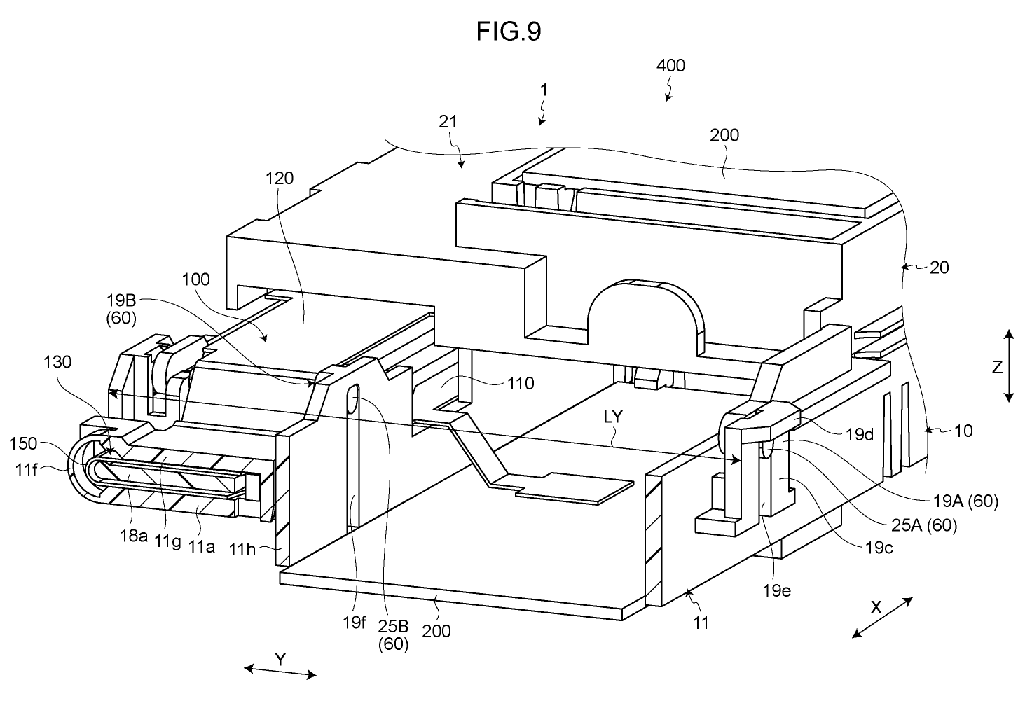

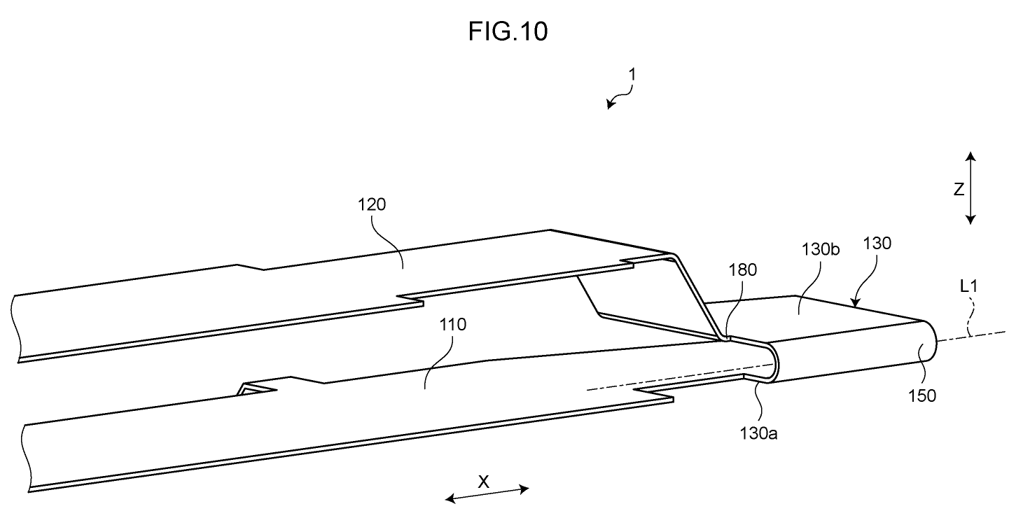

An embodiment will be described with reference to FIGS. 1-18. The present embodiment relates to a wire harness. FIG. 1 is a perspective view of a wire harness according to the embodiment, FIG. 2 is a perspective view of a flat wiring member according to the embodiment, FIG. 3 is a plan view of the flat wiring member according to the embodiment, FIG. 4 is a plan view of a case according to the embodiment, FIG. 5 is a perspective view of a case according to the embodiment, FIGS. 6-8 are plan views of the wire harness according to the embodiment, FIG. 9 is a cross-sectional view of the wire harness according to the embodiment, and FIG. 10 is a perspective view of the flat wiring member according to the embodiment.

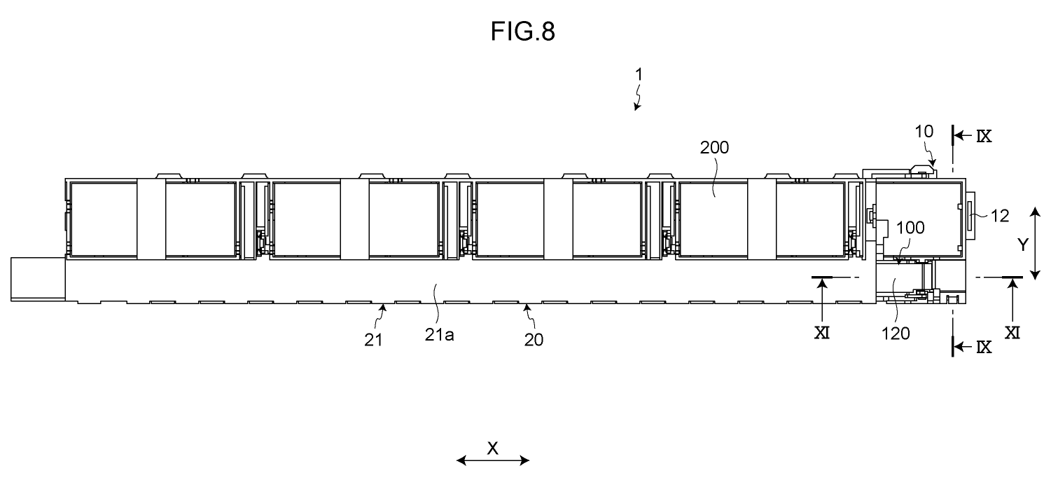

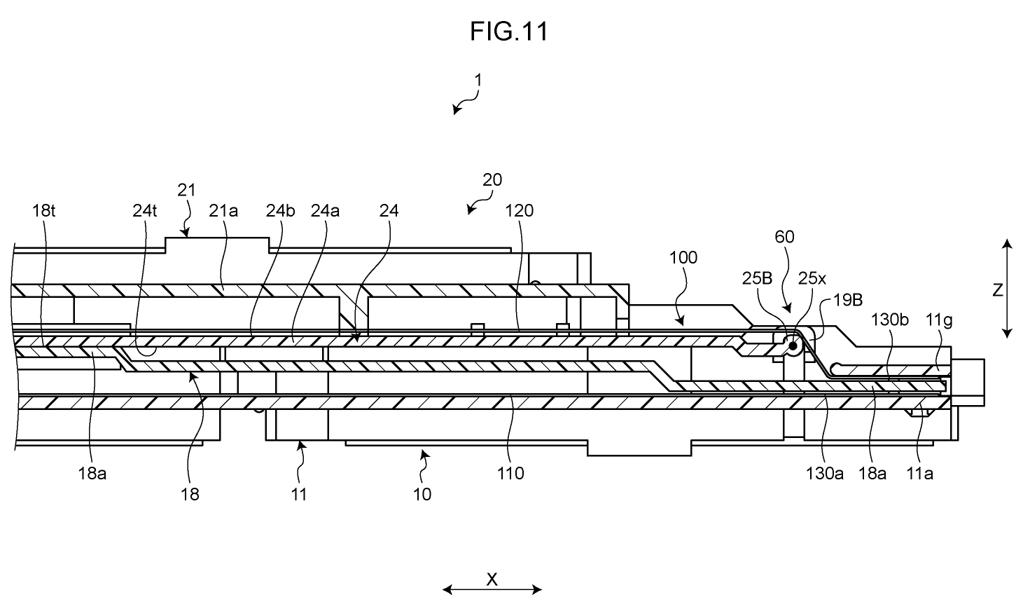

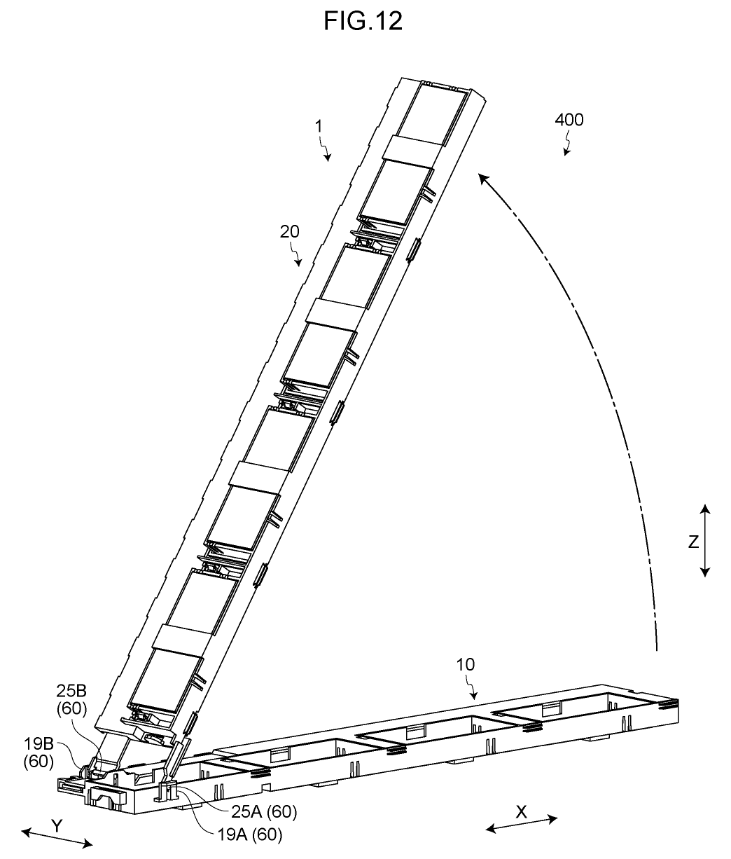

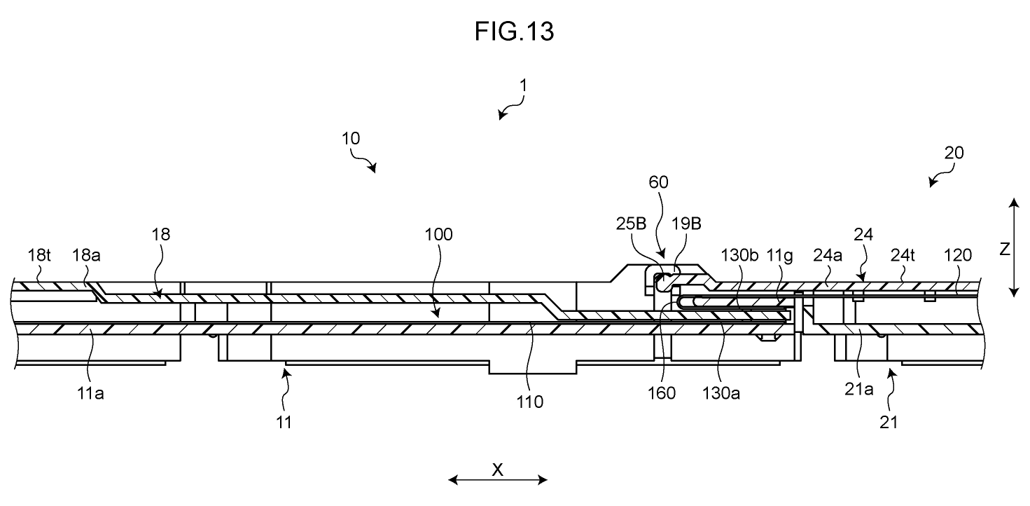

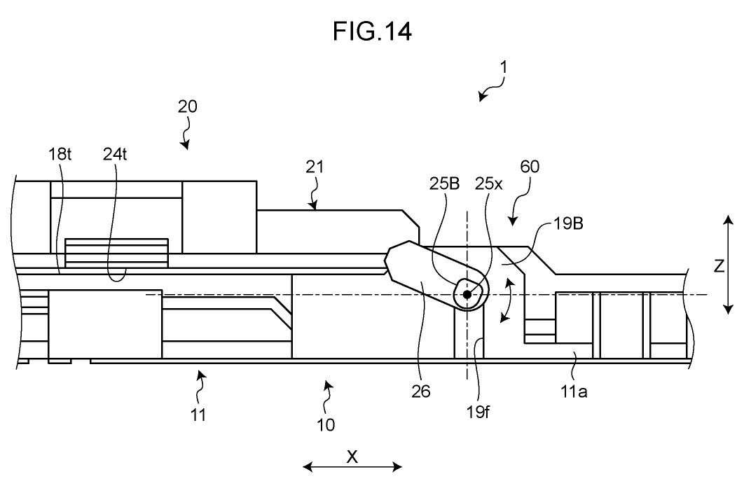

FIG. 11 is a cross-sectional view of the wire harness according to the embodiment, FIG. 12 is a perspective view of the wire harness according to the embodiment, FIG. 13 is a cross-sectional view of the wire harness according to the embodiment, and FIGS. 14-18 are diagrams illustrating an example of a rotating structure of the embodiment. FIG. 9 illustrates a cross section taken along line IX-IX in FIG. 8. FIG. 11 illustrates a cross section taken along line XI-XI of FIG. 8. FIG. 13 illustrates a cross section taken along line XIII-XIII of FIG. 1.

As illustrated in FIG. 1, a wire harness 1 of the embodiment includes a flat wiring member 100, a first case 10, a second case 20, and a rotating structure 60. As described below, the first case 10 and the second case 20 of the present embodiment can transform the flat wiring member 100 formed in a U shape into a straight line shape and hold the transformed flat wiring member 100. The first case 10 and the second case 20 are configured to engage with each other while holding the flat wiring member 100 having a straight line shape. The flat wiring member 100 in FIG. 1 is held in a straight line shape by the two cases 10 and 20.

FIG. 2 illustrates a main part of the flat wiring member 100 held in a straight line shape as illustrated in FIG. 1. FIG. 3 illustrates the U-shaped flat wiring member 100 before being transformed into a straight line shape. The flat wiring member 100 is, for example, a flexible printed circuit board (FPC). The flat wiring member 100 of the present embodiment is disposed in a battery module and detects the voltage and temperature of the battery cell of the battery module.

When the flat wiring member 100 is an FPC, the flat wiring member 100 includes a base film, a conductive layer, and a coverlay. The conductive layer is sandwiched and protected by the base film and the coverlay. The conductive layer is, for example, a conductive metal foil, and has a circuit pattern including a plurality of detection lines 140. The flat wiring member 100 has flexibility and can be bent to be wired.

The flat wiring member 100 illustrated in FIG. 3 has a substantially U shape in plan view. The flat wiring member 100 includes a first portion 110, a second portion 120, and an intermediate portion 130. The first portion 110 and the second portion 120 in plan view have substantially rectangular shapes. The flat wiring member 100 includes a slit 100s formed between the first portion 110 and the second portion 120.

The intermediate portion 130 connects an end of the first portion 110 having a straight line shape and an end of the second portion 120 having a straight line shape to each other. The intermediate portion 130 in plan view has a substantially trapezoidal shape. The intermediate portion 130 has a tapered shape whose width narrows as being farther away from the first portion 110 and the second portion 120 in the extending direction X. The extending direction X is a direction in which the first portion 110 extends and is a longitudinal direction of the first portion 110. In the flat wiring member 100 having an initial shape before transformation, the first portion 110 and the second portion 120 extend in the same extending direction X and are aligned in a width direction Y. The width direction Y is a direction orthogonal to the extending direction X, and is a width direction of the first portion 110 and the second portion 120.

The flat wiring member 100 of the present embodiment has a branch portion 170 connected to a busbar 200. The branch portion 170 extends in the width direction Y from the first portion 110 and the second portion 120. The distal end of the branch portion 170 is connected to the busbar 200 by solder, etc.

FIGS. 4 and 5 illustrate the first case 10 and the second case 20 of the present embodiment. The first case 10 and the second case 20 are molded using an insulating synthetic resin, for example. The first case 10 includes a main body 11 and a cover 18. The main body 11 and the cover 18 are integrally molded, for example. In the first case 10 of the present embodiment, the main body 11 and the cover 18 are connected to each other via a hinge portion 11e. The main body 11 includes a support wall 11a that supports the first portion 110 of the flat wiring member 100. The support wall 11a is formed in a straight line shape in the extending direction X. The cover 18 includes a facing wall 18a that covers the support wall 11a. The first portion 110 of the flat wiring member 100 is accommodated and held between the support wall 11a and the facing wall 18a.

At an end of the main body 11 in the extending direction X, there are provided a first shaft support portion 19A and a second shaft support portion 19B. The first shaft support portion 19A rotatably supports the first rotation shaft 25A of the second case 20. The second shaft support portion 19B rotatably supports the second rotation shaft 25B of the second case 20.

The second case 20 according to the embodiment includes a main body 21 and a cover 24. The main body 21 and the cover 24 are integrally molded, for example. In the second case 20 of the present embodiment, the main body 21 and the cover 24 are connected to each other via a hinge portion 21e. The main body 21 includes a support wall 21a that supports the second portion 120 of the flat wiring member 100. The support wall 21a is formed in a straight line shape in the extending direction X. The cover 24 includes a facing wall 24a that covers the support wall 21a. The second portion 120 of the flat wiring member 100 is accommodated and held between the support wall 21a and the facing wall 24a.

At an end of the main body 21 in the extending direction X, there is provided a first rotation shaft 25A. At an end of the cover 24 in the extending direction X, there is provided a second rotation shaft 25B. The first rotation shaft 25A protrudes in the width direction Y from the side surface of the main body 21. The second rotation shaft 25B extends in the width direction Y so as to cross the end of the cover 24. Both ends of the second rotation shaft 25B are supported by the second shaft support portion 19B.

In the wire harness 1 according to the embodiment, the two shaft support portions 19A and 19B of the first case 10 and the two rotation shafts 25A and 25B of the second case 20 constitute the rotating structure 60. The rotating structure 60 enables relative rotation of the two cases 10 and 20 as illustrated in FIG. 12.

As illustrated in FIG. 5, the first case 10 includes a first engagement portion 12, and the second case 20 includes a second engagement portion 22. The first engagement portion 12 is disposed at an end of the main body 11 in the extending direction X. The second engagement portion 22 is disposed at an end of the main body 21 in the extending direction X. The two engagement portions 12 and 22 are engaged with each other in a second relative position illustrated in FIG. 1.

FIG. 6 illustrates the flat wiring member 100 assembled to the first case 10 and the second case 20. The first case 10 and the second case 20 illustrated in FIGS. 4 and 6 are aligned in the width direction Y. In the present specification, regarding the first case 10 and the second case 20, a relative position in which the two cases 10 and 20 are aligned in the width direction Y is denoted as a first relative position. As illustrated in FIG. 4, when the two cases 10 and 20 are disposed in the first relative position, the support wall 11a of the first case 10 and the support wall 21a of the second case 20 are aligned in the width direction Y.

The first portion 110 of the flat wiring member 100 is accommodated in the main body 11 of the first case 10 and is supported by the support wall 11a. The step of accommodating the first portion 110 in the first case 10 is executed by an operator, for example. The second portion 120 of the flat wiring member 100 is accommodated in the main body 21 of the second case 20 and is supported by the support wall 21a. The step of accommodating the second portion 120 in the second case 20 is executed by an operator, for example. The two accommodating steps are executed in a state where the two cases 10 and 20 are held by a jig plate, for example.

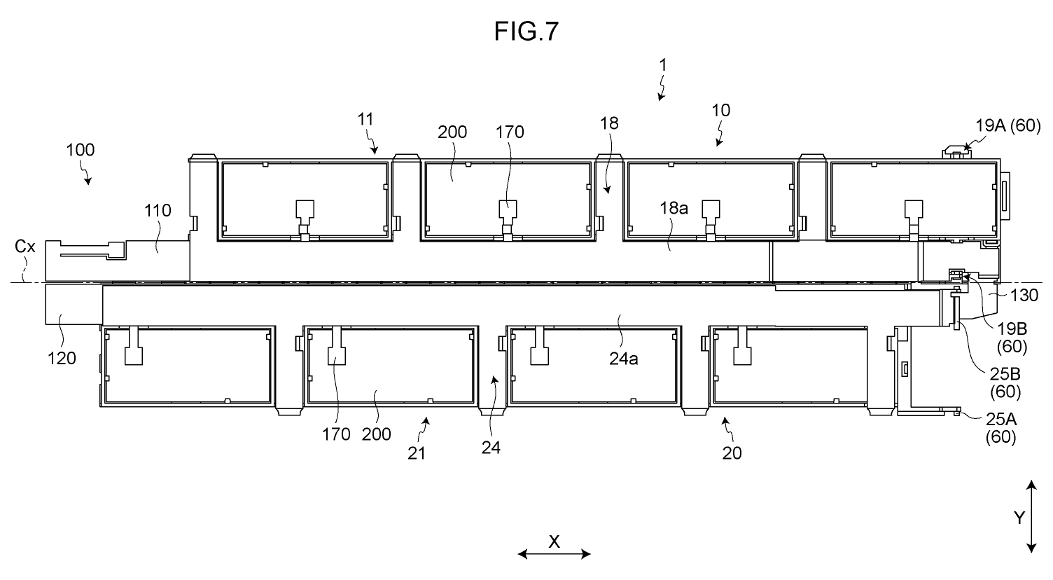

When the flat wiring member 100 has been accommodated in the two cases 10 and 20, a closing step of closing the covers 18 and 24 is executed. In the closing step, the cover 18 of the first case 10 is assembled to the main body 11 while bending the hinge portion 11e. In the closing step, the cover 24 of the second case 20 is assembled to the main body 21 while bending the hinge portion 21e. The two closing steps are executed by an operator, for example. FIG. 7 illustrates a state where the covers 18 and 24 are closed. The facing wall 18a of the cover 18 covers the first portion 110 of the flat wiring member 100. The facing wall 24a of the cover 24 covers the second portion 120 of the flat wiring member 100.

In the state illustrated in FIG. 7, a first rotation step of rotating the second case 20 relative to the first case 10 is executed. In the first rotation step, the second case 20 is rotated with respect to the first case 10 about a rotation axis Cx illustrated in FIG. 7 as a rotation center. The rotation axis Cx is a straight line extending in the extending direction X between the two covers 18 and 24, for example. The rotation at this time may be executed by using a jig plate, for example. In this case, the jig plate may include: a main body that supports the first case 10; and a support member that supports the second case 20. The support member is supported by the main body so as to be rotatable about the rotation axis Cx as a rotation center.

The second case 20 is rotated relative to the first case 10 about the rotation axis Cx as a rotation center, and the second case 20 is overlapped with the first case 10. This allows the second portion 120 of the flat wiring member 100 to overlap with the first portion 110 and face the first portion 110.

FIG. 8 illustrates a state where the first rotation step is completed and the second case 20 is overlapped with the first case 10. In the present specification, with respect to the first case 10 and the second case 20, a relative position in which the two cases 10 and 20 overlap in the height direction Z is denoted as an intermediate relative position. In the intermediate relative position, the second portion 120 of the flat wiring member 100 overlaps with the first portion 110 and faces the first portion 110. Note that the height direction Z is a direction orthogonal to both the extending direction X and the width direction Y.

Since the two cases 10 and 20 rotate about the rotation axis Cx and are positioned in the intermediate relative position, the intermediate portion 130 of the flat wiring member 100 is bent along the rotation axis Cx. FIG. 9 illustrates a cross section taken along line IX-IX of FIG. 8, and FIG. 10 illustrates the flat wiring member 100 in the state of FIG. 8. As illustrated in FIGS. 9 and 10, a first folded portion 150 is formed in the intermediate portion 130 of the flat wiring member 100.

In the first folded portion 150, the intermediate portion 130 is folded along a folding line L1 in the extending direction X. The folding line L1 is a straight line extending in the extending direction X between the two covers 18 and 24, for example. The intermediate portion 130 includes: a first region 130a connected to the first portion 110; and a second region 130b connected to the second portion 120. The intermediate portion 130 is folded back such that the first region 130a and the second region 130b face each other in the height direction Z.

As illustrated in FIG. 9, the first case 10 includes a protective cover 11g that protects the intermediate portion 130 of the flat wiring member 100. The protective cover 11g is connected to the support wall 11a via a hinge portion 11f. The protective cover 11g is engaged with the support wall 11a after the first rotation step is performed. The first case 10 accommodates the intermediate portion 130 folded back in a U shape between the support wall 11a and the protective cover 11g. The facing wall 18a of the cover 18 is sandwiched inside the folded intermediate portion 130. The hinge portion 11f covers the first folded portion 150 to protect the first folded portion 150.

As illustrated in FIG. 11, when the two cases 10 and 20 are positioned in the intermediate relative position, the second portion 120 extends along a support surface 24b. The support surface 24b is a surface included in the facing wall 24a of the cover 24, and faces the support wall 21a. The support surface 24b supports the second portion 120 and allows the second portion 120 to extend in the extending direction X.

When the first case 10 and the second case 20 are positioned in the intermediate relative position, the two cases 10 and 20 are coupled to each other by the rotating structure 60. As illustrated in FIG. 9, the first rotation shaft 25A of the second case 20 is rotatably supported by the first shaft support portion 19A of the first case 10. The first shaft support portion 19A includes: a piece portion 19c erected in the height direction Z; and a locking portion 19d. The piece portion 19c has a slit 19e extending in the height direction Z. The end of the first rotation shaft 25A is inserted into the slit 19e and locked by the locking portion 19d.

The second rotation shaft 25B of the second case 20 is rotatably supported by the second shaft support portion 19B of the first case 10. The second shaft support portion 19B includes a slit 19f provided in a side wall 11h. The side wall 11h is disposed on both sides in the width direction Y with respect to the support wall 11a. The end of the second rotation shaft 25B is inserted into the slit 19f and rotatably supported by the side wall 11h. By inserting the two rotation shafts 25A and 25B respectively into the two shaft support portions 19A and 19B, the first case 10 and the second case 20 are rotatably coupled to each other. This constitutes a busbar module 400. The busbar module 400 includes a plurality of busbars 200 and the wire harness 1 of the embodiment.

In the wire harness 1 of the present embodiment, the shaft support portions 19A and 19B are disposed at both ends in the width direction Y of the first case 10. The first shaft support portion 19A is disposed at one end of the first case 10 in the width direction Y, while the second shaft support portion 19B is disposed at the other end of the first case 10 in the width direction Y. This maximizes a lock pitch LY. The lock pitch LY is a maximum distance between the two shaft support portions 19A and 19B in the width direction Y. In other words, the lock pitch LY is the maximum distance from the point of the first rotation shaft 25A supported by the first shaft support portion 19A to the point of the second rotation shaft 25B supported by the second shaft support portion 19B.

In the wire harness 1 of the present embodiment, both ends of the second rotation shaft 25B are rotatably supported by the second shaft support portion 19B. This makes it also possible to rotate the two cases 10 and 20 relative to each other by the second rotation shaft 25B and the second shaft support portion 19B. Furthermore, the first rotation shaft 25A is rotatably supported by the first shaft support portion 19A. This increases the lock pitch LY, and improves the stability of rotation in the following second rotation step.

FIG. 12 is a diagram illustrating the second rotation step. The second rotation step is executed in a factory in which the busbar module 400 is assembled to a vehicle, etc., for example. As illustrated in FIG. 12, in the second rotation step, the second case 20 is rotated relative to the first case 10 from an intermediate relative position toward a second relative position to be described below. In the second rotation step, the second case 20 rotates relative to the first case 10 about the center axis of the two rotation shafts 25A and 25B as a rotation center.

FIG. 1 illustrates a state where the second rotation step is completed and the two cases 10 and 20 are positioned in the second relative position. In the second relative position, the first case 10 and the second case 20 are aligned in a straight line shape in the extending direction X. In this state, the first portion 110 and the second portion 120 of the flat wiring member 100 are aligned in a straight line shape. In other words, the second portion 120 is positioned on an extension line of the first portion 110 in plan view. In addition, the plurality of busbars 200 are aligned in a straight line shape in the extending direction X. The cover 18 of the first case 10 covers the first portion 110 by the facing wall 18a to protect the first portion 110. The cover 24 of the second case 20 covers the second portion 120 by the facing wall 24a to protect the second portion 120.

The second rotation step is executed to form a second folded portion 160 in the flat wiring member 100. As illustrated in FIG. 2, the second folded portion 160 is a portion folded along a folding line L2 orthogonal to the extending direction X. In the second folded portion 160, the second portion 120 is folded along the folding line L2 such that a part of the second portion 120 overlaps with the intermediate portion 130. The folding line L2 of the present embodiment is a straight line extending in the width direction Y. When the second folded portion 160 is formed, the second region 130b of the intermediate portion 130 and a proximal end 120a of the second portion 120 face each other. The proximal end 120a is an end of the second portion 120 on a side close to the intermediate portion 130.

FIG. 13 illustrates a cross section taken along line XIII-XIII of FIG. 1. That is, the cross section of FIG. 13 is a cross section in a state where the two cases 10 and 20 are positioned in the second relative position. As illustrated in FIG. 13, in the second relative position, a top surface 18t of the first case 10 and a top surface 24t of the second case 20 are located on the same plane. The top surface 18t of the present embodiment is an outer side surface of the cover 18. When the outer side surface of the cover 18 has stepped portions in the height direction Z, the top surface 18t may be a surface farthest from the support wall 11a in the height direction Z among the outer side surfaces of the cover 18. The top surface 18t may be an outer side surface of the main part of the cover 18. The top surface 24t of the present embodiment is an outer side surface of the cover 24. The top surface 24t may be an outer side surface of the main part of the cover 24.

As described below, the rotating structure 60 of the present embodiment is configured such that the two top surfaces 18t and 24t are positioned on the same plane. As illustrated in FIG. 11, rotating structure 60 includes an axis 25x. The axis 25x is an axis of the first rotation shaft 25A and the second rotation shaft 25B. The rotating structure 60 rotates the first case 10 and the second case 20 relative to each other about the axis 25x as a rotation center. The axis 25x is disposed on a plane including the top surface 24t of the second case 20. The two cases 10 and 20 overlap each other so as to bring the two top surfaces 18t and 24t into contact with each other in an intermediate relative position. At this time, the axis 25x is located on a plane including the two top surfaces 18t and 24t.

When the two cases 10 and 20 are positioned in the second relative position by the second rotation step, the top surface 24t of the second case 20 is positioned on an extension line of the top surface 18t of the first case 10 as illustrated in FIG. 13. Therefore, according to the wire harness 1 of the present embodiment, the two top surfaces 18t and 24t are positioned in appropriate positions at both occasions when the two cases 10 and 20 are in the intermediate relative position and when the two cases 10 and 20 are in the second relative position. The wire harness 1 of the present embodiment can rotate the two cases 10 and 20 relative to each other while suppressing the positional shift of the two cases 10 and 20 in the height direction Z.

Note that the rotating structure 60 may be configured to be able to adjust the position of the axis 25x. FIG. 14 illustrates the rotating structure 60 in which the position of the axis 25x is variable. The rotating structure 60 in FIG. 14 includes a swinging portion 26 provided in the second case 20. The swinging portion 26 is disposed at an end of the second case 20 in the extending direction X, for example. The swinging portion 26 is swingable with respect to the main body 21 of the second case 20. The swinging portion 26 is connected to the main body 21 via a hinge, for example. The rotation shafts 25A and 25B of the second case 20 are disposed in the swinging portion 26. When the swinging portion 26 swings with respect to the main body 21, the position of the axis 25x with respect to the main body 21 changes in the height direction Z.

In FIG. 14, the two cases 10 and 20 are positioned in the intermediate relative position. Since the position of the axis 25x is variable, the position of the axis 25x in the intermediate relative position can be brought close to the support wall 11a of the first case 10. This enables height reduction of the rotating structure 60.

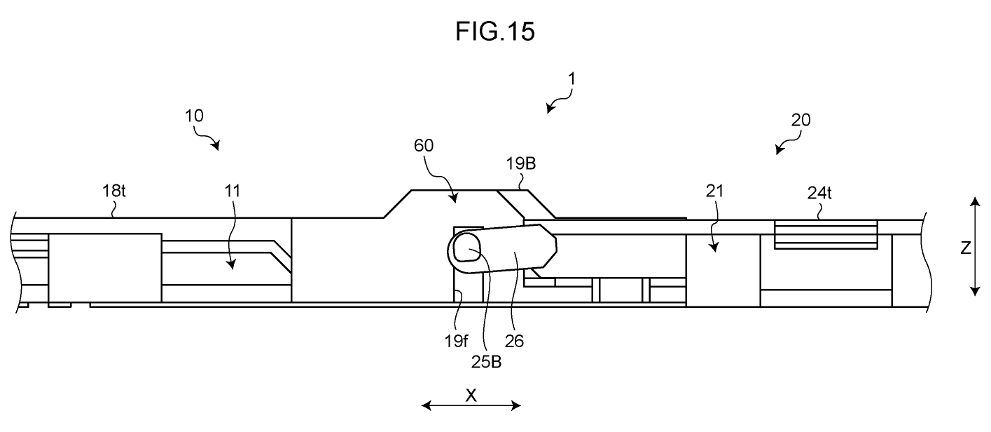

FIG. 15 illustrates two cases 10 and 20 positioned in the second relative position. The two cases 10 and 20 are fixed to each other by engagement of the first engagement portion 12 and the second engagement portion 22 illustrated in FIG. 5. As illustrated in FIG. 15, the two engagement portions 12 and 22 are configured to position the two top surfaces 18t and 24t on the same plane. The swinging portion 26 swings with respect to the main body 21 so as to position the two top surfaces 18t and 24t on the same plane when the two engagement portions 12 and 22 are engaged with each other.

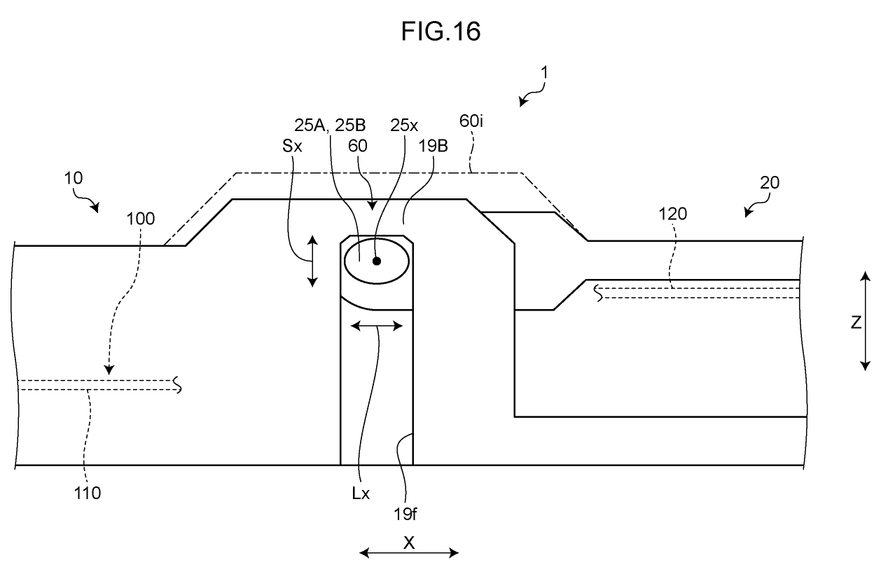

Note that the cross-sectional shapes of the rotation shafts 25A and 25B may be flat shapes. The cross-sectional shapes of the rotation shafts 25A and 25B in FIG. 16 are flat shapes each having a minor axis direction Sx and a major axis direction Lx. The minor axis direction Sx and the major axis direction Lx are orthogonal to each other. The cross-sectional shapes of the illustrated rotation shafts 25A and 25B are oval shapes. FIG. 16 illustrates a state where the first case 10 and the second case 20 are engaged with each other in a state where the flat wiring member 100 has a straight line shape. In other words, the two cases 10 and 20 in FIG. 16 are positioned in the second relative position. At this time, the minor axis direction Sx of the rotation shafts 25A and 25B is orthogonal to the extending direction X. The major axis direction Lx of the rotation shafts 25A and 25B is parallel to the extending direction X.

The rotation shafts 25A and 25B having such a cross-sectional shape enable height reduction of the wire harness 1. In FIG. 16, a one-dot chain line 60i indicates the position of the upper end of the rotating structure 60 when the cross-sectional shapes of the rotation shafts 25A and 25B are circular. When the position of the axis 25x is determined in accordance with the top surfaces 18t and 24t of the two cases 10 and 20, the height of the rotating structure 60 changes with the diameters of the rotation shafts 25A and 25B.

As can be seen from FIG. 16, by forming the cross-sectional shapes of the rotation shafts 25A and 25B into flat shapes, the rotating structure 60 in the height direction Z can be downsized. In addition, by forming the cross-sectional shapes of the rotation shafts 25A and 25B into flat shapes, the needed strength of the rotation shafts 25A and 25B can be ensured with the reduced axial length in the minor axis direction Sx.

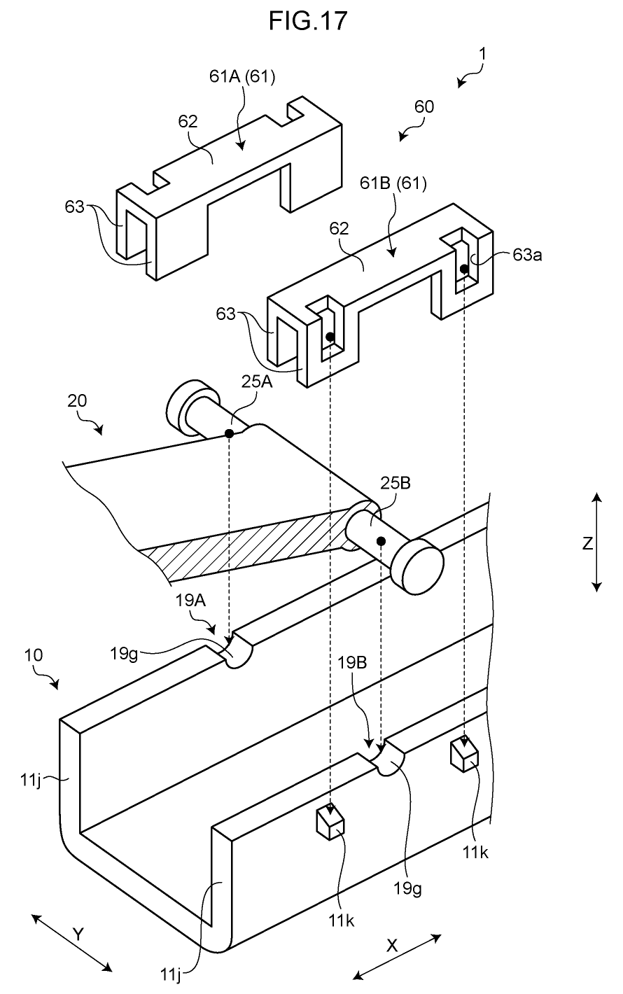

The rotating structure 60 may include a restricting member that restricts falling of the rotation shafts 25A and 25B. The rotating structure 60 illustrated in FIG. 17 includes two rotation shafts 25A and 25B, two shaft support portions 19A and 19B, and two restricting members 61. The two restricting members 61 include a first restricting member 61A and a second restricting member 61B.

Each of the shaft support portions 19A and 19B includes a support groove 19g formed in a side wall 11j of the first case 10. The shape of the support groove 19g is an arc shape. The support groove 19g of the first shaft support portion 19A rotatably supports the first rotation shaft 25A of the second case 20. The support groove 19g of the second shaft support portion 19B rotatably supports the second rotation shaft 25B of the second case 20.

The restricting member 61 is a member that engages with the first case 10 to restrict falling of the rotation shafts 25A and 25B. The restricting member 61 includes a support wall 62 and a pair of side walls 63. The pair of side walls 63 are erected from the support wall 62 and face each other. One of the side walls 63 has an engagement hole 63a. The side wall 11j has a projection 11k that locks the engagement hole 63a. The support wall 62 covers the support groove 19g and the rotation shafts 25A and 25B, and sandwiches the rotation shafts 25A and 25B between the support groove 19g and the support wall 62.

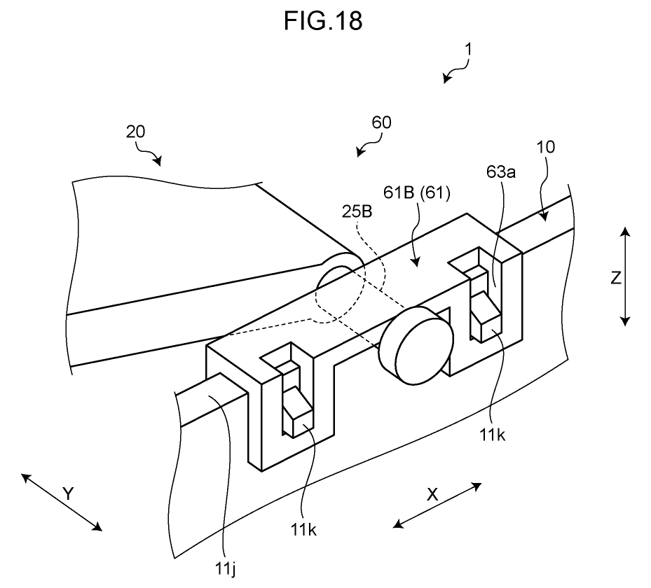

As illustrated in FIG. 18, the second restricting member 61B is engaged with the side wall 11j to hold the second rotation shaft 25B. Similarly, the first restricting member 61A is engaged with the side wall 11j to hold the first rotation shaft 25A. The holding force is improved by holding the rotation shafts 25A and 25B by the restricting member 61 which is separate from the first case 10. The restricting member 61 may be molded using a reinforced resin so as to have rigidity higher than the rigidity of the first case 10.

As described above, the wire harness 1 of the present embodiment includes the flat wiring member 100 formed in a U shape, the first case 10, the second case 20, and the rotating structure 60. The flat wiring member 100 includes the first portion 110 having a straight line shape, the second portion 120 having a straight line shape, and the intermediate portion 130 connecting the first portion 110 and the second portion 120 to each other. The first case 10 holds the first portion 110, and the second case 20 holds the second portion 120. The rotating structure 60 rotates the first case 10 and the second case 20 relative to each other.

The first case 10 and the second case 20 can be engaged with each other in a state where the flat wiring member 100 has a straight line shape. In the flat wiring member 100 having a straight line shape, the second portion 120 extends on the extension line of the first portion 110 in plan view. The flat wiring member 100 having a straight line shape includes the first folded portion 150 and the second folded portion 160. In the first folded portion 150, the intermediate portion 130 is folded along the folding line L1 in the extending direction X. In the second folded portion 160, the second portion 120 is folded along the folding line L2 orthogonal to the extending direction X so that a part of the second portion 120 overlaps the intermediate portion 130.

The rotating structure 60 is configured to form the second folded portion 160 in the second portion 120 by rotating the first case 10 and the second case 20 relative to each other. The wire harness 1 of the present embodiment can elongate the U-shaped flat wiring member 100 into a straight line shape.

The rotating structure 60 of the embodiment includes the rotation shafts 25A and 25B, and rotates the first case 10 and the second case 20 relative to each other about the axis 25x of the rotation shafts 25A and 25B as a rotation center. The first case 10 and the second case 20 respectively include the covers 18 and 24 covering the flat wiring member 100, and the top surfaces 18t and 24t which are outer side surfaces of the covers 18 and 24, and the axis 25x of the rotation shafts 25A and 25B is disposed on a plane including the top surface 24t. In the above embodiment, the rotation shafts 25A and 25B are disposed in the second case 20. Alternatively, the rotation shafts 25A and 25B may be disposed in the first case 10. In this case, the axis 25x may be disposed on a plane including the top surface 18t of the first case 10. Incidentally, when the rotation shafts 25A and 25B are disposed in the first case 10, the shaft support portions 19A and 19B may be disposed in the second case 20.

The rotating structure 60 includes the rotation shafts 25A and 25B, and rotates the first case 10 and the second case 20 relative to each other about the axis 25x of the rotation shafts 25A and 25B as a rotation center. In this case, the cross-sectional shape of the rotation shafts 25A and 25B may be a flat shape having the minor axis direction Sx. When the first case 10 and the second case 20 are engaged with each other in a state where the flat wiring member 100 has a straight line shape, the minor axis direction Sx of the rotation shafts 25A and 25B is preferably orthogonal to the extending direction X. Such a configuration enables height reduction of the rotating structure 60.

### Modification of Embodiment

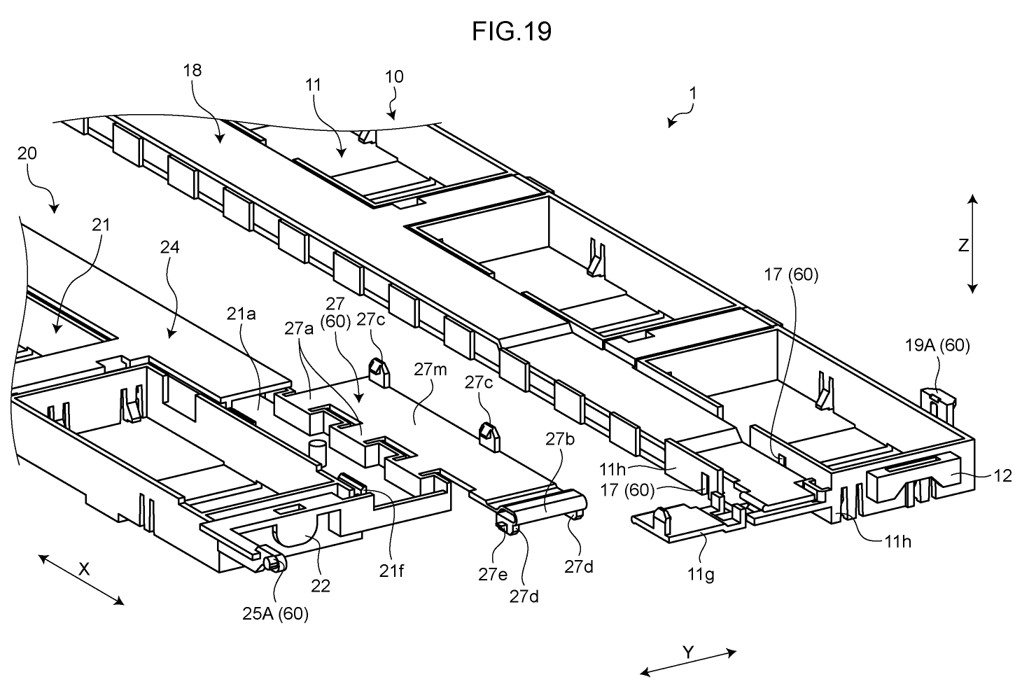

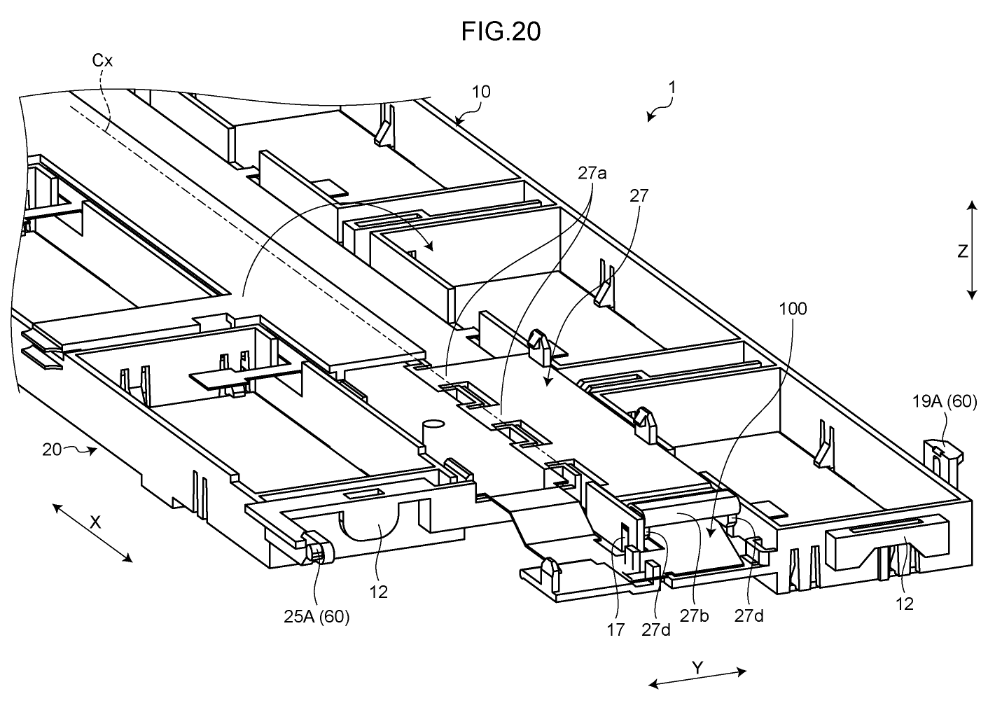

A wire harness 1 according to a modification of the embodiment will be described. FIG. 19 is a perspective view of a first case and a second case according to the modification of the embodiment, and FIGS. 20-22 are perspective views of a wire harness according to the modification of the embodiment. The wire harness 1 according to the modification of the embodiment is different from the wire harness 1 of the above embodiment in that the rotating structure 60 includes a second hinge portion 27b, for example.

As illustrated in FIG. 19, the first case 10 according to the modification of the embodiment includes a coupling portion 27 coupled to the second case 20. The coupling portion 27 constitutes the rotating structure 60. The coupling portion 27 is formed in a plate shape and protrudes in the width direction Y with respect to the main body 21. The illustrated coupling portion 27 is molded integrally with the main body 21.

The coupling portion 27 includes a main body 27m, a first hinge portion 27a, a second hinge portion 27b, a first engagement portion 27c, and a second engagement portion 27d. The main body 27m has a flat plate shape and is adjacent to the support wall 21a in the width direction Y. The main body 27m has a rectangular shape in plan view. The first hinge portion 27a connects the main body 21 of the second case 20 and the main body 27m of the coupling portion 27 to each other. The illustrated coupling portion 27 includes a plurality of first hinge portions 27a. The first hinge portion 27a is formed to be thinner than the main body 27m.

The first engagement portion 27c is a locking piece protruding from the main body 27m. The illustrated coupling portion 27 includes two first engagement portions 27c. The first engagement portion 27c is engaged with an engagement portion 21f of the second case 20 to fix the main body 27m to the main body 21.

The second hinge portion 27b is connected to an end of the main body 27m in the extending direction X. The second hinge portion 27b is formed to be thinner than the main body 27m. The second engagement portion 27d is engaged with the first case 10, and couples the second hinge portion 27b to the first case 10. The second engagement portion 27d is disposed at an end of the second hinge portion 27b in the extending direction X. More specifically, the second engagement portion 27d is disposed at an end of the second hinge portion 27b on the side opposite to the main body 27m side. The second engagement portion 27d protrudes in the height direction Z with respect to the second hinge portion 27b and includes a claw 27e. The illustrated coupling portion 27 has two second engagement portions 27d. The two second engagement portions 27d are disposed at both ends of the second hinge portion 27b in the width direction Y.

The second hinge portion 27b illustrated in FIG. 19 is curved in a substantially U shape. The second hinge portion 27b may be molded so as to have such a U shape, and may be bent when the coupling portion 27 is coupled to the first case 10.

The second case 20 includes a first rotation shaft 25A similar to that of the above embodiment. The first rotation shaft 25A is located on an extension line of the claw 27e in plan view of the second case 20. The main body 21 of the second case 20 has an arm protruding in the extending direction X, and the first rotation shaft 25A protrudes from a distal end of the arm.

The first case 10 has two engagement portions 17 corresponding to the two second engagement portions 27d. The engagement portion 17 is a part of the rotating structure 60 and holds the second engagement portion 27d. The engagement portion 17 is a slit or a recess provided in the side wall 11h of the first case 10. The claw 27e of the coupling portion 27 is inserted into the engagement portion 17 so as to be locked by the side wall 11h.

The first case 10 includes a first shaft support portion 19A similar to that of the above embodiment. The first shaft support portion 19A rotatably supports the first rotation shaft 25A of the second case 20.

As illustrated in FIG. 20, the flat wiring member 100 is assembled to the two cases 10 and 20 positioned in the first relative position. In the first relative position, the coupling portion 27 of the second case 20 is coupled to the first case 10. The engagement portion 17 of the first case 10 is engaged with the second engagement portion 27d to couple the two cases 10 and 20 to each other.

The two cases 10 and 20 can rotate relative to each other about the rotation axis Cx. The rotation axis Cx is a line in the extending direction X along the first hinge portion 27a of the coupling portion 27. In the first rotation step, the two cases 10 and 20 rotate relative to each other about the rotation axis Cx as a rotation center while transforming the first hinge portion 27a.

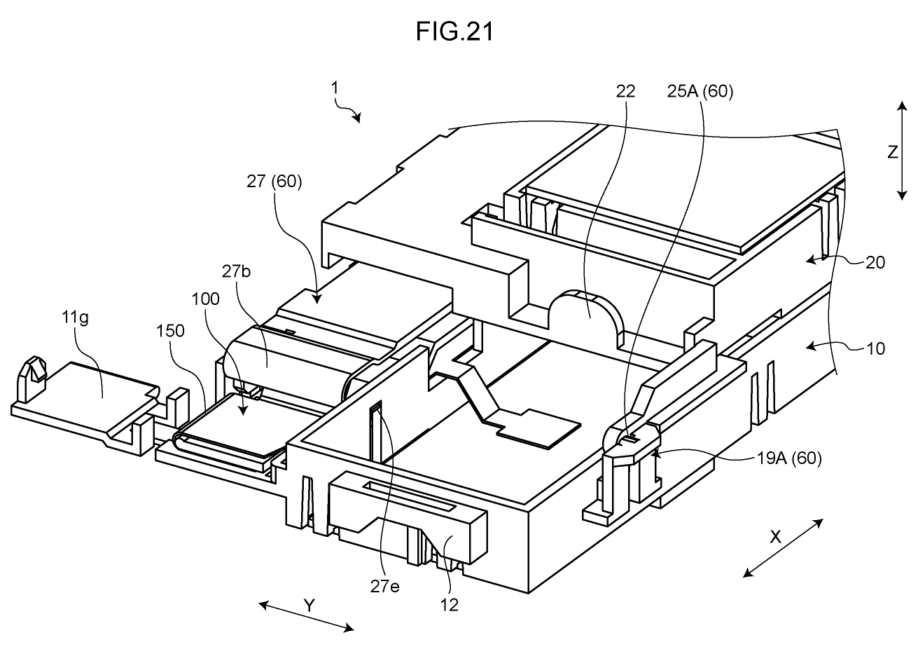

FIG. 21 illustrates the two cases 10 and 20 positioned in the intermediate relative position after the first rotation step is completed. The first rotation shaft 25A of the second case 20 is rotatably supported by the first shaft support portion 19A. By the first rotation step, the first folded portion 150 is formed in the flat wiring member 100.

The second rotation step is executed in the state illustrated in FIG. 21. In the second rotation step, the two cases 10 and 20 rotate relative to each other so as to extend the second hinge portion 27b into a straight shape. At this time, the first rotation shaft 25A and the first shaft support portion 19A can suppress the shift of the rotation center at which the two cases 10 and 20 rotate relative to each other, and can stabilize the rotation.

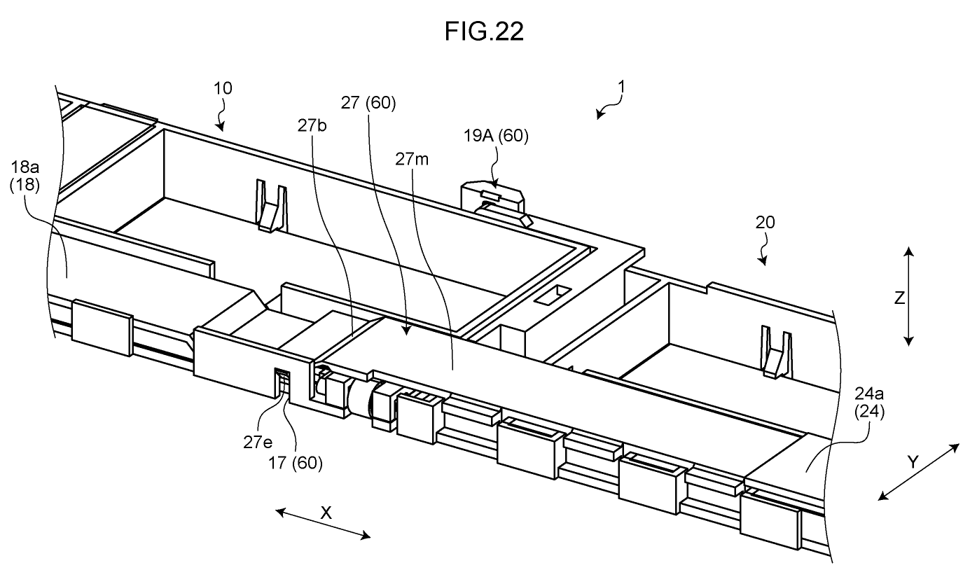

FIG. 22 illustrates two cases 10 and 20 positioned in the second relative position after the second rotation step is completed. As illustrated in FIG. 22, the second hinge portion 27b of the coupling portion 27 is transformed so as to extend in the extending direction X. The main body 27m of the coupling portion 27 functions as a cover that covers the flat wiring member 100. The main body 27m is adjacent to the cover 24 in the extending direction X, and can cover the second portion 120 of the flat wiring member 100.

The rotating structure 60 according to the modification of the embodiment includes the second hinge portion 27b provided in the coupling portion 27 that couples the first case 10 and the second case 20 to each other. The rotating structure 60 having the second hinge portion 27b enables height reduction of the rotating structure 60.

The contents disclosed in the above embodiments and modification can be executed in appropriate combination with each other.

The wire harness according to the present embodiment includes the flat wiring member formed in a U shape, the first case that holds the first portion of the flat wiring member, the second case that holds the second portion of the flat wiring member, and the rotating structure that rotates the first case and the second case relative to each other, in which the first case and the second case can be engaged with each other in a state where the flat wiring member has a straight line shape. The rotating structure is configured to form the second folded portion in the second portion of the flat wiring member by rotating the first case and the second case relative to each other. According to the wire harness of the present embodiment, there is an effect that a flat wiring member formed in a U shape can be elongated into a straight line shape.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wire harness comprising:
a flat wiring member formed in a U shape, the flat wiring member including a first portion having a straight line shape, a second portion having a straight line shape, and an intermediate portion connecting an end of the first portion and an end of the second portion to each other;
a first case that holds the first portion;
a second case that holds the second portion; and
a rotating structure that rotates the first case and the second case relative to each other, wherein
the first case and the second case can be engaged with each other in a state where the flat wiring member has a straight line shape,
the flat wiring member having a straight line shape has a configuration in which the second portion extends on an extension line of the first portion in plan view,
the flat wiring member having a straight line shape includes a first folded portion and a second folded portion,
the intermediate portion is folded along a folding line in the first folded portion, the folding line extending in an extending direction in which the first portion extends,
the second portion is folded, in the second folded portion, along a folding line orthogonal to the extending direction so as to allow a part of the second portion to overlap with the intermediate portion, and
the rotating structure is configured to form the second folded portion in the second portion by rotating the first case and the second case relative to each other.

2. The wire harness according to claim 1, wherein
the rotating structure includes a rotation shaft and rotates the first case and the second case relative to each other about an axis of the rotation shaft as a rotation center,
the first case and the second case each include: a cover that covers the flat wiring member; and a top surface that is an outer side surface of the cover, and
the axis of the rotation shaft is disposed on a plane including the top surface.

3. The wire harness according to claim 1, wherein
the rotating structure includes a rotation shaft and rotates the first case and the second case relative to each other about an axis of the rotation shaft as a rotation center,
a cross-sectional shape of the rotation shaft is a flat shape having a minor axis direction, and
when the first case and the second case are engaged with each other in a state where the flat wiring member has a straight line shape, the minor axis direction of the rotation shaft is orthogonal to the extending direction.

4. The wire harness according to claim 1, wherein
the rotating structure includes a hinge portion provided in a coupling portion that couples the first case and the second case to each other.
